(19) United States
(12) Patent Application Publication
(10) Pub. No.: US 2015/0040981 A1
(43) Pub. Date: Feb. 12, 2015

(54) DURABLE PHOTOVOLTAIC MODULES

(71) Applicant: 3M INNOVATIVE PROPERTIES COMPANY, SAINT PAUL, MN (US)

(72) Inventors: Scott R. Meyer, Woodbury, MN (US); Mark K. Nestegard, Long Lake, MN (US)

(21) Appl. No.: 14/385,004

(22) PCT Filed: Feb. 13, 2013
(86) PCT No.: PCT/US2013/025818

§ 371 Date: Sep. 12, 2014

Related U.S. Application Data
(60) Provisional application No. 61/611,254, filed on Mar. 15, 2012.

(51) Int. Cl. H01L 31/0203

(52) U.S. Cl. CPC H01L 31/0203
USPC 136/259; 438/64

(57) ABSTRACT

The present disclosure generally relates to durable photovoltaic modules, methods of making durable photovoltaic modules, and constructions including durable photovoltaic cells and modules.

### TECHNICAL FIELD

The present disclosure generally relates to durable photovoltaic modules, methods of making durable photovoltaic modules, and constructions including durable photovoltaic cells and modules.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources. One of the promising energy resources today is sunlight. Globally, millions of households currently obtain power from solar photovoltaic systems. The rising demand for solar power has been accompanied by a rising demand for devices and materials capable of fulfilling the requirements for these applications.

Photovoltaic modules used outdoors and are thus subject to continuous exposure to the elements. Consequently, a technical challenge in designing and manufacturing photovoltaic modules and their components is achieving long-term (e.g., 25 years) durability when subjected to harsh environmental conditions, including, for example, water vapor and sunlight.

### SUMMARY

Mechanical properties, optical clarity, corrosion, ultraviolet light stability, and resistance to outdoor weather conditions are all factors that can contribute to the gradual degradation of the materials in a photovoltaic cell or module over an extended period of operation. Additionally, photovoltaic cells can be damaged by the mechanical mechanisms that hold the cells together (e.g., clips). Also, mechanical damage can occur during module/cell handling and transportation prior to installation. Consequently, there is a need for durable photovoltaic cells and modules. Additionally, there exists a need for one or more of: photovoltaic devices with improved efficiency and photovoltaic devices with reduced cost.

The inventors of the present disclosure discovered methods of forming, materials, and constructions for a more durable photovoltaic module and/or cell capable of long-term outdoor use. The formation of more durable photovoltaic modules and/or cells can increase the useful life of a photovoltaic module. Increased life can result in decreased cost of solar power generation, which may lead to faster and/or wider adoption of this form of green energy generation.

One embodiment of the present disclosure relates to a photovoltaic cell, comprising: a front-side layer having a first major surface that is exposed to sunlight and a second major surface that is adjacent to a first major surface of an electricity-generating layer; and an edge-protecting material that covers substantially all of the edges of the front-side layer and the electricity-generating layer.

Another embodiment of the present disclosure relates to a photovoltaic cell, comprising: a front-side layer exposed to sunlight; an electricity-generating layer adjacent to the front-side layer; and an edge-protecting material that covers substantially all of the edges of the front-side layer and the electricity-generating layer.

Another embodiment of the present disclosure relates to a photovoltaic cell, comprising: a solar cell construction having first and second opposing major surfaces, first and second opposing minor surfaces, and first and second opposing edges, the solar cell construction including: a front-side layer; a solar cell adjacent to the front-side layer; an edge-protecting material that covers substantially all of the first and second opposing edges of the solar cell construction and a portion of each of the first and second major surfaces of the solar cell construction.

Any embodiment of the present disclosure may include one or more of the following. The photovoltaic cell or module as described in any of the various embodiments wherein the electricity-generating layer is a solar cell. The photovoltaic cell or module as described in any of the various embodiments wherein the edge-protecting material is a multilayer material that includes a polymer layer and an adhesive layer. The photovoltaic cell or module as described in any of the various embodiments wherein the polymer layer includes a fluoropolymer. The photovoltaic cell or module as described in any of the various embodiments wherein the adhesive layer includes a pressure sensitive adhesive. The photovoltaic cell or module as described in any of the various embodiments wherein the adhesive layer includes a thermoset adhesive. The photovoltaic cell or module as described in any of the various embodiments wherein the cell or module further includes an encapsulant layer adjacent to the electricity-generating layer. The photovoltaic cell or module as described in any of the various embodiments wherein the cell or module further includes a backside layer adjacent to the encapsulant layer. The photovoltaic cell or module as described in any of the various embodiments wherein the cell or module includes an edge-protecting material that covers at least s portion of or substantially all of the edges of the individual layers in the photovoltaic cell. The photovoltaic cell or module as described in any of the various embodiments wherein the front-side layer is one of glass, quartz, and a multilayer film.

Another embodiment of the present disclosure is a method of making a photovoltaic module, comprising: positioning an energy-generating layer adjacent to a front-side layer to form an energy-generating layer—front-side layer construction; and applying an edge-protecting material to opposing edges of the energy-generating layer—front-side layer construction.

Any embodiment of the present disclosure may include one or more of the following. A method wherein positioning an energy-generating layer involves depositing a semiconductive layer onto the front-side layer. A method further including depositing an encapsulant material onto the energy-generating layer. A method further including curing the encapsulant layer. A method further including positioning a backside layer adjacent to the encapsulant layer. A method further including applying an edge-protecting material to opposing edges of the photovoltaic module.

These and various other features and advantages will be apparent from reading the following detailed description.

### BRIEF DESCRIPTION OF DRAWING

FIG. 1 is a cross-sectional schematic view of a prior art photovoltaic module.

FIG. 2 is a cross-sectional schematic view of an edge-sealed photovoltaic module.

FIG. 3 is a cross-sectional schematic view of one embodiment of an edge-sealed photovoltaic cell.

FIG. 4 is a cross-sectional schematic view of one embodiment of an edge-sealed photovoltaic module.

FIG. 5 is a cross-sectional schematic view of one embodiment of an edge-sealed photovoltaic module.

FIG. 6 is a cross-sectional schematic view of one embodiment of an edge-sealed photovoltaic cell.

FIG. 7 is a cross-sectional schematic view of one embodiment of an edge-sealed photovoltaic module.

### DETAILED DESCRIPTION

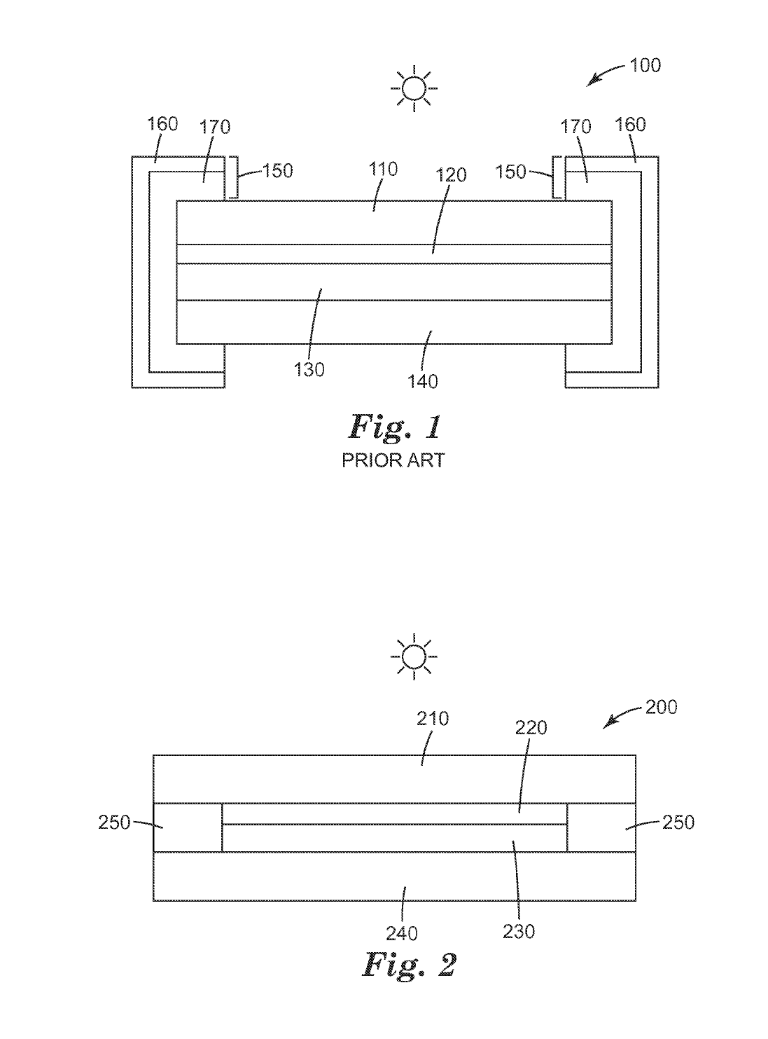

Two attempts have been made to increase the durability of photovoltaic modules. The first attempt to form a durable photovoltaic module is shown schematically in FIG. 1. Photovoltaic module 100 includes a front-side layer 110, a solar cell 120 (i.e., an electricity-generating layer), an encapsulant layer 130, and a backside glass layer 140, all of which are edge-wrapped by a multilayer film 150 including a fluoropolymer layer 160 and a pressure-sensitive adhesive layer 170. A construction of this general type was described, for example, in JP2011032451. One of the disadvantages of this construction is that a separate edge-wrapping step has to be conducted, often by the photovoltaic cell installer.

The second attempt to form a durable photovoltaic module is shown schematically in FIG. 2. Photovoltaic module 200 includes a front-side layer 210, a solar cell 220 (i.e., an electricity-generating layer), an encapsulant layer 230, and a backside layer 240. The solar cell 220 and the encapsulant layer 230 are partially edge-sealed by an edge seal material 250 (e.g., a butyl rubber). One of the disadvantages of this construction is that the amount of energy generated by a photovoltaic module is proportional to the amount of surface area of the photovoltaic cell exposed to sunlight. Because this construction reduces the total photovoltaic cell surface area available to incident sunlight in favor of partial edge sealing, the total energy production of the photovoltaic module is decreased. As a result, the per unit energy generation cost of the photovoltaic module is increased.

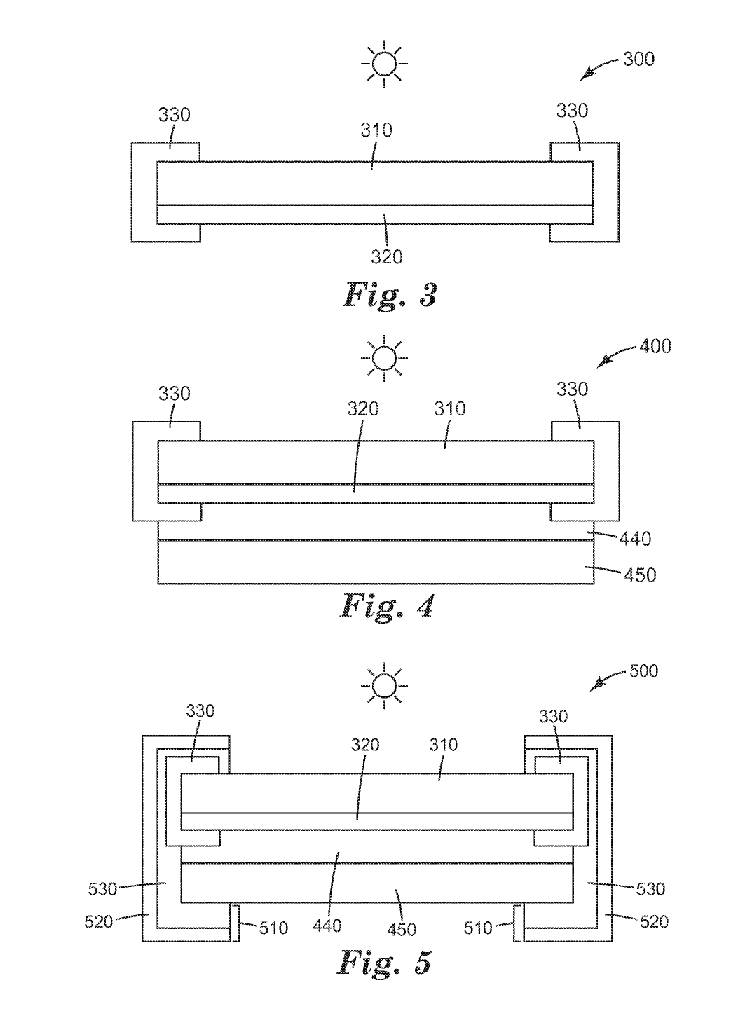

The inventors of the present disclosure discovered that various manufacturing and durability benefits could be achieved by providing edge protection to a construction consisting of the front-side layer and the photovoltaic cell. As shown schematically in FIG. 3, one embodiment of a photovoltaic cell 300 in accordance with the teachings herein includes a front-side layer 310 and a solar cell 320 (i.e., an electricity-generating layer) that are adjacent to an edge-protecting material 330. In the specific embodiment shown in FIG. 3, edge-protecting material 330 wraps around the edges of the front-side layer 310—solar cell 320 construction. In some embodiments, edge-protecting material is on at least a portion of each of the major surfaces of the front-side layer—solar cell construction. In the specific embodiment shown in FIG. 3, edge-protecting material 330 is a single layer, but edge-protecting material can also be a multilayer. In some implementations, for example, edge-protecting material 330 is a multilayer film including a polymer layer (e.g., fluoropolymer) and an adhesive layer (e.g., pressure sensitive adhesive, thermoset, UV-curable, or combination thereof). In some embodiments, the edge-protecting material is a tape.

The embodiment shown in FIG. 3 can be manufactured using various methods. One exemplary method involves positioning solar cell 320 adjacent to front-side layer 310 to form a solar cell—front-side layer construction. In some embodiments, the solar cell is a semiconductive layer that is deposited onto front-side surface. An edge-protecting material 330 is then applied to the edges of the solar cell—front-side layer construction. In some embodiments, the edge-protecting material is a tape. In some embodiments, the tape substantially covers the edges of the solar cell-front-side layer construction. In some embodiments, the tape also covers at least a portion of at least one the major surfaces of the solar-cell—front-side layer construction. In some embodiments, the edge-protecting material covers all or a majority or some of at least one of the major surfaces of at least one of the solar cell and the front-side layer.

As shown schematically in FIG. 4, photovoltaic module 400 includes the edge-protected solar cell—front-side layer construction of FIG. 3. An encapsulant layer 440 is adjacent to solar cell 320, and a backside layer 450 is adjacent to the encapsulant layer. In some embodiments, the encapsulant layer and backside layer are applied or positioned as shown in FIG. 4 in one or more separate process steps after the construction of FIG. 3 is formed.

Various methods can be used to manufacture photovoltaic module 400. In one exemplary embodiment, an encapsulant is deposited onto the exposed major surface of the solar cell in the edge-wrapped solar cell—front-side layer construction of FIG. 3. In some embodiments, the encapsulant is cured (e.g., thermally cured) and is then positioned adjacent to a backside layer.

In some embodiments, the edge-protecting material (including, for example, the polymer film and adhesive) is applied to the front-side layer 310 and solar cell 320. Then, encapsulant material 440 and backside layer 450 is applied. The resulting construction is run through a thermal encapsulation process which cures the edge protecting material and the encapsulant.

As shown schematically in FIG. 5, an edge-protecting material is placed on the edges of photovoltaic module 400. More specifically, as shown in FIG. 5, the edges of photovoltaic module construction 400 of FIG. 4 (described in greater detail above) are substantially covered by an edge-protecting material 510. In the exemplary embodiment shown in FIG. 5, at least a portion of the top and bottom major surfaces of photovoltaic module 400 are also covered by an edge-protecting material, but in some embodiments, the edge-protecting material is only minimally on the major surfaces or not on the major surfaces. The exemplary edge-protecting material shown in FIG. 5 is a multilayer material including a polymer layer 520 and an adhesive layer 530, but any edge-protecting material could be used.

Various methods can be used to manufacture photovoltaic module 500. In one exemplary embodiment, a second edge-protecting material is applied to the photovoltaic module 400. In some embodiments, the additional edge-protecting material is applied after the encapsulant is applied and cured and after the backside glass is positioned adjacent to the cured encapsulant.

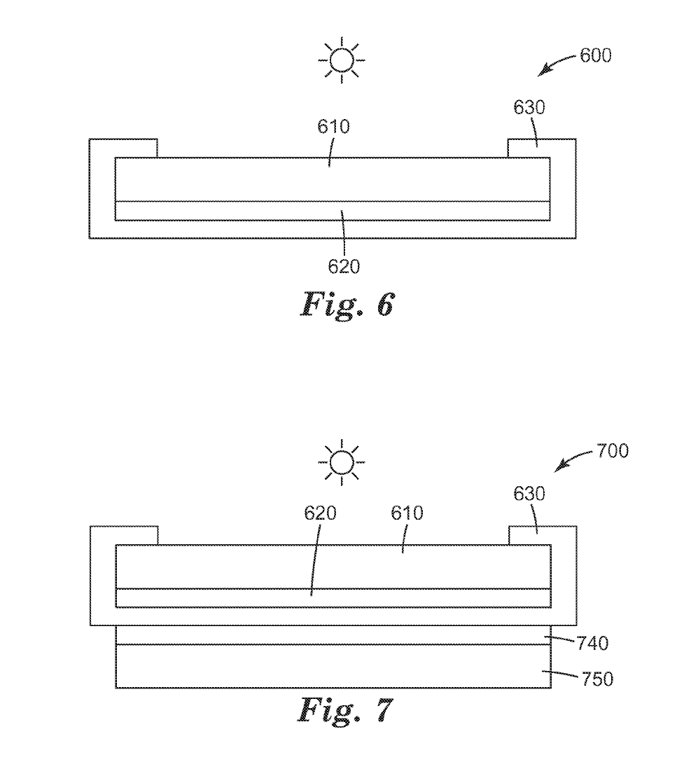

As shown schematically in FIG. 6, one exemplary alternative embodiment of a photovoltaic cell 600 in accordance with the teachings herein includes a front-side layer 610 and a solar cell 620 (i.e., an electricity-generating layer) that are adjacent to an edge-protecting material 630. In the specific embodiment shown in FIG. 6, edge-protecting material 330 wraps around the edges of the front-side layer 610—solar cell 620 construction as well as across a major surface of the solar cell 620.

As shown schematically in FIG. 7, photovoltaic module 700 includes the edge-protected solar cell—front-side layer construction of FIG. 6. An encapsulant layer 740 is adjacent to solar cell 620, and a backside layer 750 is adjacent to encapsulant layer 740. In some embodiments, the encapsulant layer and backside layer are applied or positioned as shown in FIG. 7 in one or more separate process steps after the construction of FIG. 6 is formed.

Each of the individual layers of the photovoltaic cells and modules described herein are discussed in greater detail below.

Front-Side Layer

In some embodiments, front-side layer includes a type of glass or quartz. In some embodiments, the glass is thermally tempered. Some exemplary glass materials include soda-lime-silica based glass. In some embodiments, the front-side layer has a low iron content (e.g., less than about 0.10% total iron, more preferably less than about 0.08, 0.07 or 0.06% total iron) and/or an antireflection coating thereon to optimize light transmission.

In some embodiments, the front-side layer is a barrier layer. Some exemplary barrier layers are those described in, for example, U.S. Pat. Nos. 7,186,465, 7,276,291, 5,725,909, 6,231,939, 6,975,067, 6,203,898, 6,348,237, 7,018,713, and 6,696,157 and U.S. Publication Nos. 2007/0020451 and 2004/0241454, all of which are incorporated herein by reference.

Solar Cell

Any solar cell can be used. Some examples of photovoltaic cells include thin film solar cells (like Copper Indium Gallium di-Selenide (CIGS)), CIS (CuInSe₂) cells, a-Si (amorphous silicon) cells, c-Si (crystalline silicon), and organic photovoltaic devices (OPVs).

Edge-Protecting Material

Any edge-protecting material can be used that accomplishes at least one of the following objectives: (1) provide electrical insulation of the solar cell; (2) provide some degree of moisture-resistance; (3) provide some degree of visible and/or UV light-resistance or blocking; and (4) provide some degree of resistance to mechanical injury by clips and during handling and transportation prior to or during installation.

In some embodiments, the edge-protecting material is at least one of transparent, semi-transparent, and opaque (e.g., causes a reduction in transmission of visible light having a wavelength of between about 380 nm and about 750 nm). In some embodiments, the edge-protecting material reduces transmission of light having a wavelength between about 380 and about 450 nm. In some embodiments, the edge-protecting material permits a maximum transmission of 20% of light having a wavelength between about 380 nm and about 450 nm. In some embodiments, the edge-protecting material permits a maximum transmission of 2% of light having a wavelength between about 380 and about 450 nm. In some embodiments, the edge-protecting material permits a maximum transmission of 0.2% of light having a wavelength between about 380 and about 450 nm. In some embodiments, the edge-protecting material is a transparent tape.

In some embodiments, the edge-protecting material is a tape that include a polymer layer and an adhesive layer. In some embodiments, the polymer layer includes a fluoropolymer. Some exemplary fluoropolymers include ETFE and PTFE. In some embodiments, extruded PTFE is preferred. The desired fluoropolymer thickness would depend on the electrical breakdown resistance. One exemplary thickness range is between about 0.1 mils and about 6 mils. Another exemplary thickness range is between about 1 mil and about 2 mils.

In some embodiments, the adhesive is one or more of a thermoset adhesive, a hot melt adhesive, a solvent-based adhesive, and a pressure sensitive adhesive. In some embodiments, the adhesive is a thermoset pressure sensitive adhesive. In some embodiments, the thermoset pressure sensitive adhesive cures during the encapsulation cure cycle.

In some embodiments, the adhesive is transparent after the cure cycle. In some embodiments, the desired transparency is at least 80% transparency to visible light. In some embodiments, the desired transparency is at least 90% to visible light.

In some embodiments, the PSA does not flow and has sufficient barrier properties to provide slow or minimal infiltration of oxygen and moisture through the adhesive bond line. Also, in some embodiments, the PSA is generally transmissive to visible and infrared light such that it does not interfere with absorption of visible light, for example, by photovoltaic cells. The PSAs may have an average transmission over the visible portion of the spectrum of at least about 75% (in some embodiments at least about 80, 85, 90, 92, 95, 97, or 98%) measured along the normal axis. In some embodiments, the PSA has an average transmission over a range of 400 nm to 1400 nm of at least about 75% (in some embodiments at least about 80, 85, 90, 92, 95, 97, or 98%). Exemplary PSAs include acrylates, silicones, polyisobutylenes, ureas, and combinations thereof. Some useful commercially available PSAs include UV curable PSAs such as those available from Adhesive Research, Inc., Glen Rock, PA, under the trade designations “ARclear 90453” and “ARclear 90537” and acrylic optically clear PSAs available, for example, from 3M Company, St. Paul, Minn., under the trade designations “OPTICALLY CLEAR LAMINATING ADHESIVE 8171”, “OPTICALLY CLEAR LAMINATING ADHESIVE 8172CL”, and “OPTICALLY CLEAR LAMINATING ADHESIVE 8172PCL”.

In some embodiments, the PSA has a modulus (tensile modulus) up to 50,000 psi (3.4×10⁸ Pa). The tensile modulus can be measured, for example, by a tensile testing instrument such as a testing system available from Instron, Norwood, MA, under the trade designation “INSTRON 5900”. In some embodiments, the tensile modulus of the PSA is up to 40,000, 30,000, 20,000, or 10,000 psi (2.8×10⁸ Pa, 2.1×10⁸ Pa, 1.4×10⁸ Pa, or 6.9×10⁸ Pa).

In some embodiments, the PSA is an acrylic or acrylate PSA. As used herein, the term “acrylic” or “acrylate” includes compounds having at least one of acrylic or methacrylic groups. Useful acrylic PSAs can be made, for example, by combining at least two different monomers (first and second monomers). Exemplary suitable first monomers include 2-methylbutyl acrylate, 2-ethylhexyl acrylate, isooctyl acrylate, lauryl acrylate, n-decyl acrylate, 4-methyl-2-pentyl acrylate, isoamyl acrylate, sec-butyl acrylate, and isononyl acrylate. Exemplary suitable second monomers include a (meth)acrylic acid (e.g., acrylic acid, methacrylic acid, itaconic acid, maleic acid, and fumaric acid), a (meth)acrylamide (e.g., acrylamide, methacrylamide, N-ethyl acrylamide, N-hydroxyethyl acrylamide, N-octyl acrylamide, N-t-butyl acrylamide, N,N-dimethyl acrylamide, N,N-diethyl acrylamide, and N-ethyl-N-dihydroxyethyl acrylamide), a (meth)acrylate (e.g., 2-hydroxyethyl acrylate or methacrylate, cyclohexyl acrylate, t-butyl acrylate, or isobornyl acrylate), N-vinyl pyrrolidone, N-vinyl caprolactam, an alpha-olefin, a vinyl ether, an allyl ether, a styrenic monomer, or a maleate. Acrylic PSAs may also be made by including cross-linking agents in the formulation.

In some embodiments, PSAs useful for practicing the present disclosure comprise polyisobutylene. The polyisobutylene may have a polyisobutylene skeleton in the main or a side chain. Useful polyisobutylenes can be prepared, for example, by polymerizing isobutylene alone or in combination with n-butene, isoprene, or butadiene in the presence of a Lewis acid catalyst (for example, aluminum chloride or boron trifluoride).

Useful polyisobutylene materials are commercially available from several manufacturers. Homopolymers are commercially available, for example, under the trade designations “OPPANOL” and “GLISSOPAL” (e.g., OPPANOL B15, B30, B50, B100, B150, and B200 and GLISSOPAL 1000, 1300, and 2300) from BASF Corp. (Florham Park, NJ); “SDG”, “JHY”, and “EFROLEN” from United Chemical Products (UCP) of St. Petersburg, Russia. Polyisobutylene copolymers can be prepared by polymerizing isobutylene in the presence of a small amount (e.g., up to 30, 25, 20, 15, 10, or 5 weight percent) of another monomer such as, for example, styrene, isoprene, butene, or butadiene. Exemplary suitable isobutylene/isoprene copolymers are commercially available under the trade designations “EXXON BUTYL” (e.g., EXXON BUTYL 065, 068, and 268) from Exxon Mobil Corp., Irving, Tex.; “BK-1675N” from UCP and “LANXESS” (e.g., LANXESS BUTYL 301, LANXESS BUTYL 101-3, and LANXESS BUTYL 402) from Sarnia, Ontario, Canada. Exemplary suitable isobutylene/styrene block copolymers are commercially available under the trade designation “SIBSTAR” from Kaneka (Osaka, Japan). Other exemplary suitable polyisobutylene resins are commercially available, for example, from Exxon Chemical Co. under the trade designation “VISTANEX”, from Goodrich Corp., Charlotte, N.C., under the trade designation “HYCAR”, and from Japan Butyl Co., Ltd., Kanto, Japan, under the trade designation “JSR BUTYL”.

The edge-protecting material can have any desired length, width, and thickness. In some embodiments, the PSA layer disclosed herein is at least 0.005 mm (in some embodiments, at least 0.01, 0.02, 0.03, 0.04, or 0.05 mm) in thickness. In some embodiments, the PSA layer has a thickness up to about 0.2 mm (in some embodiments, up to 0.15, 0.1, or 0.075 mm) in thickness. For example, the thickness of the PSA layer may be in a range from 0.005 mm to 0.2 mm, 0.005 mm to 0.1 mm, or 0.01 to 0.1 mm.

In some embodiments, the edge-protecting material exhibits stability in either or both acidic conditions (e.g., acid rain) and basic conditions (e.g., exposure to herbicides and/or cleaning solutions).

Encapsulant Layer

Any encapsulant can be used in methods and constructions of the present disclosure. Some exemplary encapsulant types include curable thermosets, thermosettable fluoropolymers, and acrylics. Some exemplary encapsulants include ethylene vinyl acetate (EVA), polyvinyl butyral (PVB), polyolefins, thermoplastic urethanes, clear polyvinylchloride, and ionomers. One exemplary commercially available polyolefin encapsulant is PO8500™, sold by 3M Company. Both thermoplastic and thermoset polyolefin encapsulants can be used. In some embodiments, encapsulants of the types generally described in U.S. patent application Ser. Nos. 61/555,892 and 61/555,912 can be used, the disclosure of each of which is hereby incorporated herein. In some embodiments, an encapsulant can be applied over and around the photovoltaic cell and associated circuitry.

In some embodiments, an integrated backsheet-encapsulant can be used instead of a separate backside layer and encapsulant layer. Some exemplary integrated backsheet-encapsulants include, for example, those described in PCT Patent Application Nos. PCT/2011/061918 and PCT/2011/061950 and U.S. patent application Ser. No. 61/562,899, the disclosure of each of which is hereby incorporated herein.

Backside Layer

In some embodiments, backside layer includes a type of glass or quartz. In some embodiments, the glass is thermally tempered. Some exemplary glass materials include soda-lime-silica based glass.

In some embodiments, the backside layer is a backsheet. Exemplary backsheets are polymeric films, and in many embodiments are multilayer polymer films. One commercially available example of a backsheet films is the 3M™ Scotchshield™ film commercially available from 3M Company, Saint Paul, Minn. Exemplary backsheets are those that include extruded PTFE. The backsheet may be connected to a building material, such as a roofing membrane (for example, in building integrated photovoltaics (BIPV)).

Some of the processing techniques described herein can be introduced as in-line processes. In some embodiments, only the downweb edges will be addressed. In some embodiments, all edges are edge-protected as described herein.

All references mentioned herein are incorporated by reference.

As used herein, the words “on” and “adjacent” cover both a layer being directly on and indirectly on something, with other layers possibly being located therebetween.

As used herein, the terms “major surface” and “major surfaces” refer to the surface(s) with the largest surface area on a three-dimensional shape having three sets of opposing surfaces. As used herein, the term “minor surface” and “minor surfaces” refers to the surface(s) with the second largest surface area on a three-dimensional shape having three sets of opposing surfaces. As used herein, the terms “edge” and “edges” refer to the surfaces with the smallest surface area on a three-dimensional shape having three sets of opposing surfaces.

Unless otherwise indicated, all numbers expressing feature sizes, amounts, and physical properties used in the present disclosure and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this disclosure and the appended claims, the term “or” is generally employed in its sense including “and/or” unless the content clearly dictates otherwise.

Various embodiments and implementation of the present disclosure are disclosed. The disclosed embodiments are presented for purposes of illustration and not limitation. The implementations described above and other implementations are within the scope of the following claims. One skilled in the art will appreciate that the present disclosure can be practiced with embodiments and implementations other than those disclosed. Those having skill in the art will appreciate that many changes may be made to the details of the above-described embodiments and implementations without departing from the underlying principles thereof. It should be understood that this invention is not intended to be unduly limited by the illustrative embodiments and examples set forth herein and that such examples and embodiments are presented by way of example only with the scope of the invention intended to be limited only by the claims set forth herein as follows. Further, various modifications and alterations of the present invention will become apparent to those skilled in the art without departing from the spirit and scope of the present disclosure. The scope of the present application should, therefore, be determined only by the following claims.

1. A photovoltaic cell, comprising:
a front-side layer having a first major surface that is exposed to sunlight and a second major surface that is adjacent to a first major surface of an electricity-generating layer; and
an edge-protecting material that covers substantially all of the edges of the front-side layer and the electricity-generating layer
wherein the electricity-generating layer has a first major surface and a second major surface, and
wherein the edge-protecting material is adjacent to a portion of a major surface of the front-side layer and is adjacent to a portion of a major surface of the electricity-generating layer.

2. The photovoltaic cell of claim 1, wherein the electricity-generating layer is a solar cell.

3. The photovoltaic cell of claim 1, wherein the edge-protecting material is a multilayer material that includes a polymer layer and an adhesive layer.

4. (canceled)

5. The photovoltaic cell of claim 3, wherein the adhesive layer includes a pressure sensitive adhesive.

6. The photovoltaic cell of claim 3, wherein the adhesive layer includes a thermoset adhesive.

7. The photovoltaic cell of claim 1, further comprising:
an encapsulant layer adjacent to the electricity-generating layer.

8. The photovoltaic cell of claim 7, further comprising:
a backside layer adjacent to the encapsulant layer.

9. The photovoltaic cell of claim 8, further comprising:
an edge-protecting material that covers the edges of each of the layers in the photovoltaic cell.

10. (canceled)

11. (canceled)

12. (canceled)

13. (canceled)

14. (canceled)

15. (canceled)

16. (canceled)

17. (canceled)

18. (canceled)

19. (canceled)

20. A photovoltaic cell, comprising:
a solar cell construction having first and second opposing major surfaces, first and second opposing minor surfaces, and first and second opposing edges, the solar cell construction including:
a front-side layer;
a solar cell adjacent to the front-side layer;
an edge-protecting material that covers substantially all of the first and second opposing edges of the solar cell construction and a portion of each of the first and second major surfaces of the solar cell construction.

21. The photovoltaic cell of claim 20, wherein the backside layer is one of glass, quartz, and a backsheet.

22. The photovoltaic cell of claim 20, wherein the edge-protecting material is multilayer and includes a polymer layer and an adhesive layer.

23. (canceled)

24. The photovoltaic cell of claim 22, wherein the adhesive layer includes a pressure sensitive adhesive.

25. The photovoltaic cell of claim 22, wherein the adhesive layer includes a thermoset adhesive.

26. The photovoltaic cell of claim 20, further comprising:
an encapsulant layer adjacent to the solar cell layer.

27. The photovoltaic cell of claim 26, further comprising:
a backside layer adjacent to the encapsulant layer.

28. The photovoltaic cell of claim 27, further comprising:
an edge-protecting material that covers the edges of each of the layers in the photovoltaic cell.

29. (canceled)

30. (canceled)

31. A method of making a photovoltaic module, comprising:
positioning an energy-generating layer adjacent to a front-side layer to form an energy-generating layer—front-side layer construction; and
applying an edge-protecting material to opposing edges of the energy-generating layer—front-side layer construction
wherein the front-side layer has a first major surface and a second major surface,
wherein the electricity-generating layer has a first major surface and a second major surface, and wherein the edge-protecting material is adjacent to a portion of a major surface of the front-side layer and is adjacent to a portion of a major surface of the electricity-generating layer.

32. The method of claim 31, wherein positioning an energy-generating layer involves depositing a semiconductive layer onto the front-side layer.

33. The method of claim 31, further comprising:
depositing an encapsulant material onto the energy-generating layer.

34. (canceled)

35. The method of claim 3, further comprising:
positioning a backside layer adjacent to the encapsulant layer.

36. (canceled)
